(19) United States
(12) Patent Application Publication
(10) Pub. No.: US 2026/0052966 A1
(43) Pub. Date: Feb. 19, 2026

(54) SEMICONDUCTOR STRUCTURES AND FABRICATION METHODS THEREOF

(71) Applicant: Yangtze Memory Technologies Holding Co., Ltd., Hubei (CN)

(72) Inventors: Min Wen, Wuhan (CN); Liang Xiao, Wuhan (CN); Lina Miao, Wuhan (CN); WenBin Zhou, Wuha (CN); ZongLiang Huo, Wuhan (CN)

(21) Appl. No.: 19/297,951

(22) Filed: Aug. 12, 2025

(30) Foreign Application Priority Data
Aug. 15, 2024 (CN) 202411125339.4

(51) Int. Cl. H01L 23/00; H01L 23/48; H01L 25/065

(52) U.S. Cl. CPC H01L 24/08; H01L 23/481; H01L 24/80; H01L 25/0657; H01L 24/05; H01L 2224/05557; H01L 2224/05611; H01L 2224/05647; H01L 2224/05655; H01L 2224/08145; H01L 2224/80895; H01L 2224/80896; H01L 2225/06541; H01L 2225/06565

(57) ABSTRACT

Examples of the present application provide a semiconductor structure and a fabrication method thereof, relate to the field of semiconductor chip technologies, and aim to stack more device layers in a semiconductor structure and in turn increase the number of the device layers packaged in the semiconductor structure. The semiconductor structure provided by an example of the present application includes a plurality of stack layers that are stacked and a first bonding structure, wherein two adjacent stack layers are connected together through the first bonding structure; the stack layer includes a plurality of device layers that are stacked and a second bonding structure with two adjacent device layers connected through the second bonding structure. After connecting device layers together through the second bonding structure, the thickness of the device layers can be reduced.

### CROSS-REFERENCE TO RELATED APPLICATIONS

This application claims priority to and the benefit of Chinese Patent Application 2024111253394, filed on Aug. 15, 2024, which is hereby incorporated by reference in its entirety.

### TECHNICAL FIELD

The present application relates to the field of semiconductor chip technology, and particularly to a semiconductor structures and a fabrication methods thereof.

### BACKGROUND

A plurality of chips can be stacked and packaged into a memory. Each chip is configured to store data. The total quantity of the data that all the chips can store is the largest capacity of the memory.

### BRIEF DESCRIPTION OF DRAWINGS

In order to explain technical solutions in the present application more clearly, accompanying drawings required by some examples of the present application will be described briefly hereafter. It is obvious that the drawings described below are only for some examples of the present application and other drawings can be obtained according to those drawings by those skilled in the art. Moreover, the accompanying drawings described below may be considered as schematic diagrams, instead of limitation on actual sizes of a product, the actual flow of a method, actual timing of signals involved in examples of the present application.

FIG. 1 is a first structural diagram of a semiconductor structure in an example of the present application;

FIG. 2 is a structural diagram of a device layer;

FIG. 3 is a second structural diagram of a semiconductor structure in an example of the present application;

FIG. 4 is a third structural diagram of a semiconductor structure in an example of the present application;

FIG. 5 is a fourth structural diagram of a semiconductor structure in an example of the present application;

FIG. 6 is a first structural diagram illustrating a portion of a side wall of a semiconductor structure in an example of the present application;

FIG. 7 is a second structural diagram illustrating a portion of a side wall of a semiconductor structure in an example of the present application;

FIG. 8 is an enlarged view of the portion A in FIG. 1;

FIG. 9 is a flowchart illustrating a fabrication method of a semiconductor structure in an example of the present application;

FIG. 10 is a structural diagram after formation of third connection sections in the example of the present application;

FIG. 11 is a structural diagram of connection structures;

FIG. 12 is a structural diagram after formation of fourth connection sections in an example of the present application;

FIG. 13 is a structural diagram after formation of second bonding structures in an example of the present application;

FIG. 14 is a first structural diagram after formation of first connection sections in the example of the present application;

FIG. 15 is a first structural diagram after formation of second connection sections in an example of the present application;

FIG. 16 is a first structural diagram after formation of first bonding structures in an example of the present application;

FIG. 17 is a second structural diagram after formation of first connection sections in an example of the present application;

FIG. 18 is a second structural diagram after formation of second connection sections in an example of the present application;

FIG. 19 is a second structural diagram after formation of first bonding structures in an example of the present application;

FIG. 20 is a block diagram of a memory system in accordance with some examples; and

FIG. 21 is a block diagram of a memory system in accordance with some other examples.

### DETAILED DESCRIPTION

Technical solutions in some examples of the present application will be described below clearly and completely with reference to accompanying drawings. It is obvious that the examples to be described are only some, not all, examples of the present application. All other examples obtained by those skilled in the art based on the examples provided in the present application fall within the scope claimed by the present application.

In the description of the present application, it is understood that orientation and position relationships indicated by terms “center”, “upper”, “lower”, “front”, “back”, “left”, “right”, “vertical”, “horizontal”, “top”, “bottom”, “inner”, “outer” and the like are those based on the drawings and only for the purpose of facilitating and simplifying the description of the present application. There is no indication or implication that the devices or elements as referred to must have any particular orientations and positions, or be constructed or operated in any particular orientations and positions. As a result, they should not be understood as any limitation on the present application.

In the whole specification and claims, the term “include” or “comprise” should be interpreted to be open and inclusive, e.g. to have the meaning of “include or comprise, but not limited to”, unless indicated otherwise in the context. In the description of the specification, terms “one implementation”, “some implementations”, “example examples”, “illustratively” or “some examples” are intended to mean that specific features, structures, materials or characteristics related to the implementation (s) or example(s) are included in at least one implementation or example of the present application. The expression by the above-mentioned terms may not necessarily refer to one and the same implementation or example. Moreover, the specific features, structures, materials or characteristics may be included in one or more implementations or examples in any suitable way.

Hereafter, the terms “first”, “second” etc. are only configured for the purpose of description and should not be understood to indicate or imply relative importance or to designate the number of the referenced technical features implicitly. Therefore, a feature being qualified by “first” or “second” may indicate explicitly or implicitly that one or more instances of the feature are included. In description of examples of the present application, the expression of “a plurality of” means two or more unless otherwise specified.

In description of some examples, terms “couple” and “connect” as well as their derivative expressions may be used. For example, in description of some examples, the term “connect” may be used to indicate that two or more components are direct physical or electrical contact with each other. For another example, in description of some examples, the term “couple” may be used to indicate that two or more components are in direct physical or electrical contact. However, the term “couple” may also indicate that two or more components are not in direct contact with each other, but still cooperate or interact. Examples of the present disclosure are not necessarily limited by what is described herein.

“At least one of A, B and C” and “at least one of A, B or C” have the same meaning and both include the following combinations of A, B and C: only A; only B; only C; a combination of A and B; a combination of A and C; a combination of B and C; and a combination of A, B and C.

The phrase “A and/or B” includes three combinations: only A, only B and A and B.

As used herein, “about”, “generally” or “approximately” includes the stated value and a mean value in an acceptable deviation range of a certain value, wherein the acceptable deviation range is determined by those of ordinary skill in the art considering the measurements under discussion and errors, namely limitations of the measurement system, related to measurements of a certain quantity.

In contents of the present application, the meanings of “on”, “over” and “above” should be interpreted in the broadest manner such that “on” not only means “directly on” something but also includes the meaning of “on” something with an intermediate feature or a layer therebetween, and that “over” or “above” not only means the meaning of “over” or “above” something but can also include the meaning of “above” or “over” something with no intermediate feature or layer therebetween (e.g., directly on something).

Example implementations are described herein with reference to cross-sectional views and plan views as idealized illustrative figures. In the figures, thicknesses of layers and regions are exaggerated for clarity. Therefore, it can be appreciated that deviation from the shape of the figures may be caused by, for example, manufacturing processes and/or tolerances. Therefore, example implementations should not be interpreted to be limited to the shape of the region illustrated herein, but include deviation in shape caused by, for example, manufacturing. For example, an etched region of a rectangular shape usually has curved features. Therefore, the regions shown in the figures are illustrative in nature and their shapes are not intended to depict actual shapes of regions of a device and also not intended to limit the scope of example implementations.

During production of chips, due to the limitation on the total height of the package, the number of the chips that can be stacked and packaged is limited, thus limiting the total capacity of the memory.

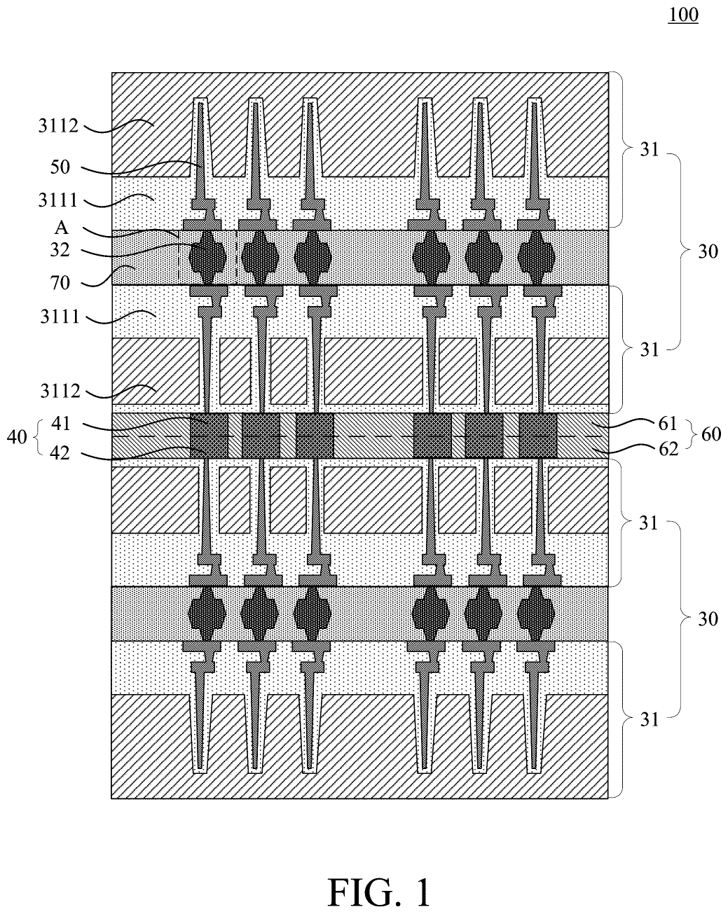

Referring to FIG. 1, an example of the present application provides a semiconductor structure 100 including a plurality of stack layers 30 and a first bonding structure 40. The plurality of stack layers 30 are stacked in their thickness direction. The first bonding structure 40 is located between two adjacent stack layers 30, and the two adjacent stack layers 30 are connected by the first bonding structure 40. Here, the stack layers 30 may include a plurality of device layers 31 and a second bonding structure 32. The plurality of device layers 31 are stacked in their thickness direction. The second bonding structure 32 is located between two adjacent device layers 31, and the two adjacent device layers 31 are connected by the second bonding structure 32.

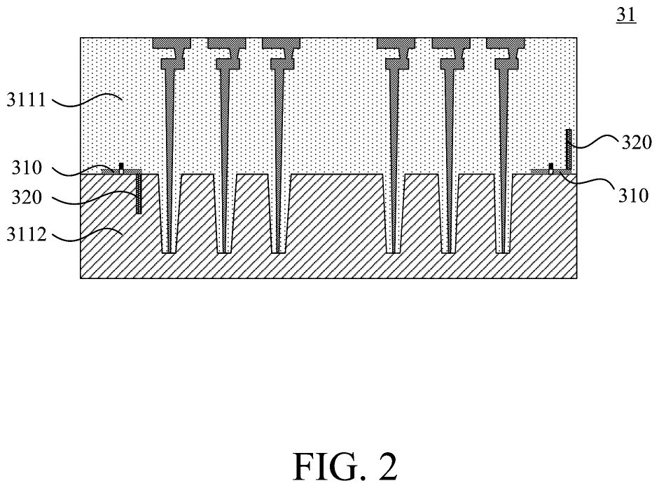

In the above-described example, the device layer 31 may include a first device sublayer 3111 and a second device sublayer 3112. Here, with reference to FIG. 2, the device layer 31 may include transistors 310 disposed on a surface of the second device sublayer 3112 facing the first device sublayer 3111. The transistor 310 may include a complementary metal oxide semiconductor (CMOS) transistor. The device layer 31 may be a dynamic random access memory (DRAM) device or an NAND device. In an implementation, in which the device layer 31 is a DRAM, the device layer 31 may further include a storage capacitor 320 that is connected with the transistor 310 and configured to store data, wherein the storage capacitor 320 may be located in the first device sublayer 3111 or in the second device sublayer 3112. The second device sublayer 3112 is located on a side of the first device sublayer 3111 and covers the first device sublayer 3111. During stacking of the plurality of device layers 31, single device layer 31 needs to be transferred. The second device sublayer 3112 can increase the thickness of the whole device layer 31, so that damage to the device layer 31 during transfer due to a too small thickness of the device layer 31 can be avoided. Illustratively, the first device sublayer 3111 may include an insulating material, and the second device sublayer 3112 may include a semiconductor material, such as silicon, germanium or the like.

Referring to FIG. 1, in order for the plurality of device layers 31 that are stacked to be interconnected in the stacking direction, the device layer 31 may further include a connection structure 50 extending through the first device sublayer 3111 and the second device sublayer 3112. That is, the connection structure 50 has one end exposed at a side of the first device sublayer 3111 away from the second device sublayer 3112 and the other end exposed at a side of the second device sublayer 3112 away from the first device sublayer 3111. The connection structure 50 is electrically connected with various devices in the device layer 31. One exposed end of the connection structure 50 is configured to be connected with the second bonding structure 32. In such a configuration, after the plurality of device layers 31 are stacked, the connection structure 50 and the second bonding structure 32 may enable interconnection of the plurality of device layers 31 in the stacking direction. Here, the connection structure 50 may include a conductive material, such as copper, titanium nitride or the like.

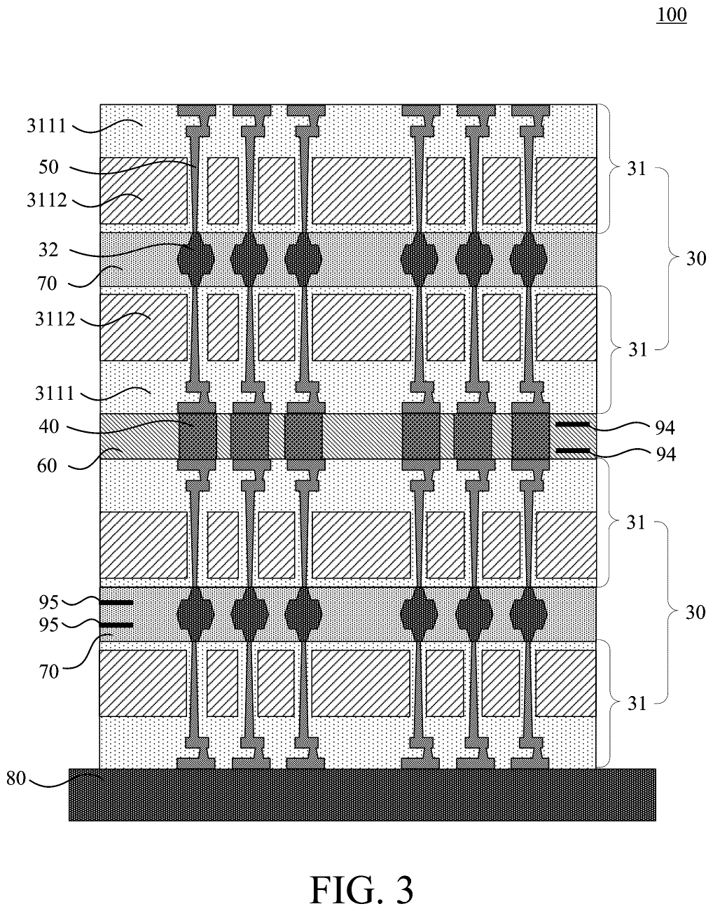

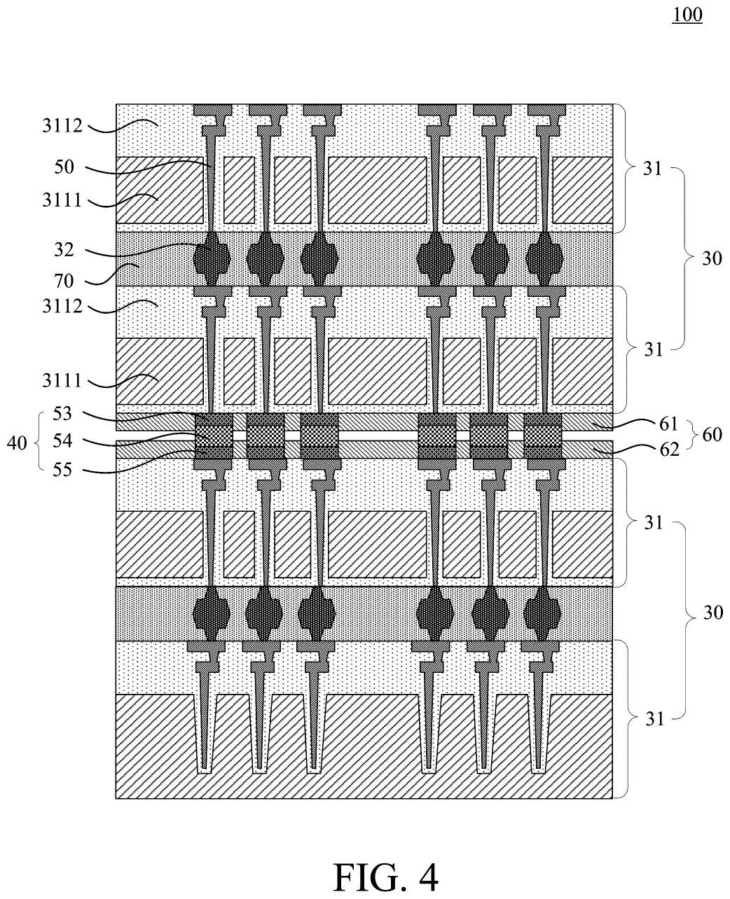

In combination with an example, in which the stack layer 30 includes two device layers 31, with reference to FIG. 1, in some implementations, the end of the connection structure 50 away from the second device sublayer 3112 is connected with the second bonding structure 32. That is, two adjacent device layers 31 have their first device sublayers 3111 proximate to each other and connected with each other through the second bonding structure 32 to form the stack layer 30. Referring to FIG. 3, in some other implementations, the end of the connection structure 50 away from the first device sublayer 3111 is connected with the second bonding structure 32, e.g. two adjacent device layers 31 have their second device sublayers 3112 proximate to each other and connected with each other through the second bonding structure 32 to form the stack layer 30. Referring FIG. 4, in some other implementations, the end of the connection structure 50 away from the second device sublayer 3112 in one device layer 31 is connected with the end of the connection structure 50 away from the first device sublayer 3111 in another device layer 31 through the second bonding structure 32, e.g. the first device sublayer 3111 of one device layer 31 and the second device sublayer 3112 of another device layer 31 are proximate to each other and connected with each other through the second bonding structure 32 to form the stack layer 30.

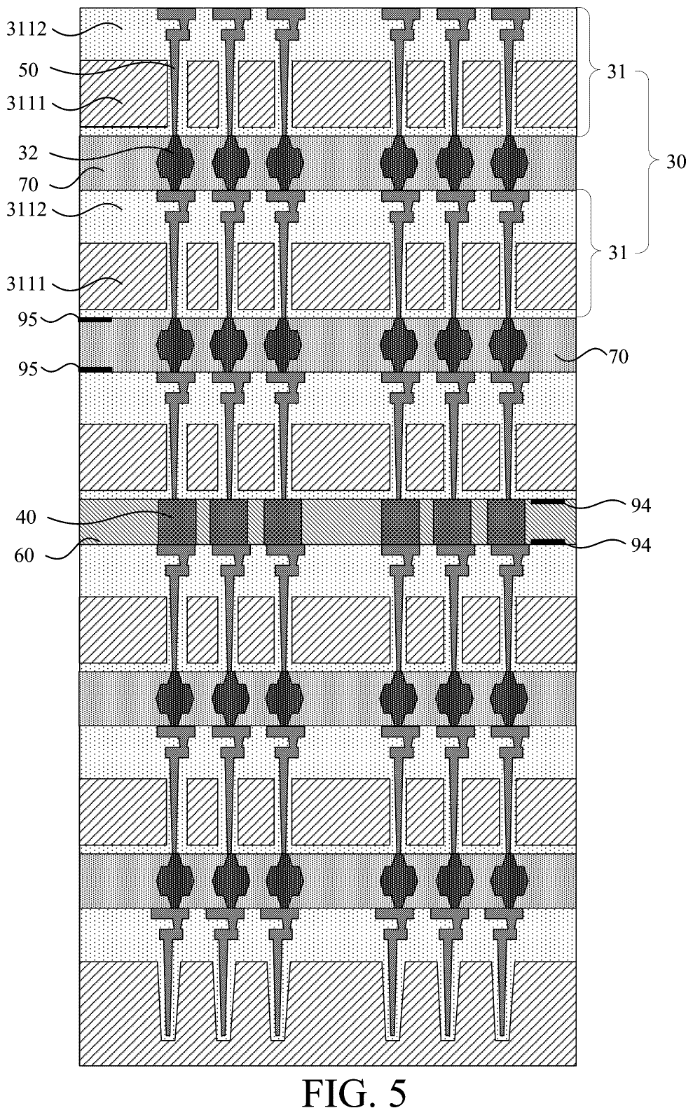

Referring to FIG. 5, in combination with an example, in which the stack layer 30 includes three or more device layers 31, for every two adjacent device layers 31, the first device sublayer 3111 of one device layer 31 is proximate to and combined with the second device sublayer 3112 of another device layer 31. Through the above-described configuration, during formation of a stack layer 30 by stacking the device layers 31, the first device layer 31 of the plurality of device layers 31 within the same stack layer 30 faces the same direction, so that the operations of inverting device layers 31 can be reduced, the efficiency of formation of stack layers 30 can be improved and in turn the efficiency of formation of the semiconductor structure 100 can be improved.

Referring FIGS. 1, 6 and 7, in some examples, device layers 31 may be formed on a wafer and a plurality of device layers 31 may be disposed in an array on one wafer. Every two device layers 31 have a dicing street formed therebetween. In some implementations, two or more wafers are interconnected to form a wafer set, and the respective device layers 31 on any two wafers may be considered to have one-to-one correspondence.

In the above-described implementations, the individual wafers are stacked together and diced simultaneously to form the stack layers 30. The method for dicing the wafers may include blade dicing or blade sawing, laser dicing and plasma dicing. It can be understood that no matter how high the dicing precision is, dicing traces 93 may be left on cutting surfaces after they are magnified some times. The present application is not limited in the shape of the dicing trace 93. In the same stack layer 30, the dicing traces 93 are continuous on the side walls (e.g. the cutting surfaces) of two device layers 31 connected through the same second bonding structure 32. Since the second bonding structure 32 is located within a second insulating layer 70, the dicing traces 93 on the side walls of the device layers 31 on the upper and lower sides of the second insulating layer 70 are continuous.

However, after formation of stack layers 30 by dicing, a plurality of stack layers 30 are connected together through first bonding structures 40 and the dicing traces 93 on side walls of different stack layers 30 connected through the same first bonding structure 40 are discontinuous. Since a first bonding structure 40 is located in a first insulating layer 60, the dicing traces 93 on the side walls of the stack layers 30 on the upper and lower sides of the first insulating layer 60 are continuous.

In the example of the present application, during wafer stacking, at least two wafers are connected through the second bonding structures 32 to form a wafer set. Then the wafer set is diced to form the stack layers 30, which are connected through the first bonding structures 40. Through the above-described configuration, the thickness is increased by stacking individual wafers to prevent the device layers 31 from being damaged during transfer; after connecting the device layers 31 together through the second bonding structures 32, thickness of the second device sublayers 3112 in the device layers 31 on the respective wafers may be reduced, so that thickness of the device layers 31 can be reduced. Thereby during formation of the semiconductor structure 100 by connecting the stack layers 30 through the first bonding structure 40, more device layers 31 may be stacked within the semiconductor structure 100 of the same size, so that the number of the device layers 31 packaged in the semiconductor structure 100 can be increased, and in turn the total capacity of the semiconductor structure 100 can be improved.

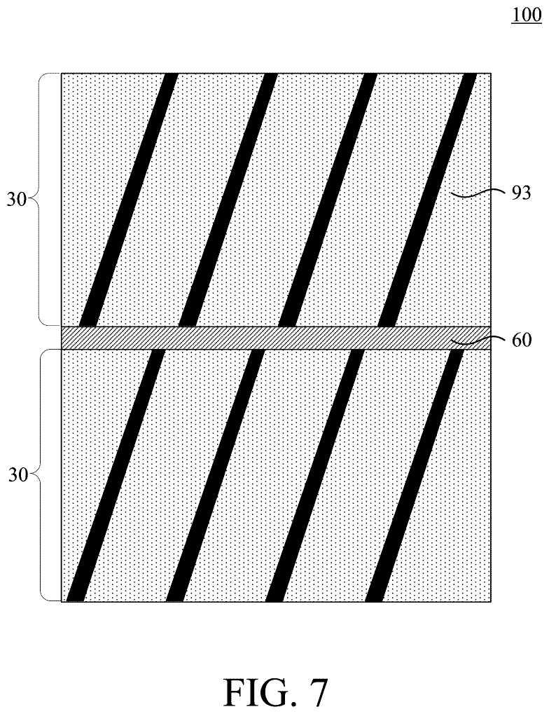

Referring to FIGS. 1 and 7, in the example of the present application, the semiconductor structure 100 further includes the first insulating layer 60 located between two adjacent stack layers 30 with the first bonding structure 40 located therein. In combination with the implementation, in which the plurality of stack layers 30 after being diced are connected through the first bonding structures 40, the dicing traces 93 are only present on side walls of the stack layers 30, rather than the side walls of the first insulating layers 60, so that the dicing traces 93 are disconnected at the first insulating layers 60.

Referring to FIGS. 3 and 5, in an implementation, in which two stack layers 30 are connected through the first bonding structure 40 to form the semiconductor structure 100, one stack layer 30 has a first mark 94 that is disposed at the side to be connected with the other stack layer 30, the first mark 94 configured for alignment between the stack layers 30. Illustratively, during interconnection of the stack layers 30, the first mark 94 on one stack layer 30 should be aligned with the first mark 94 on the other stack layer 30, so that the connection structure 50 in one stack layer 30 may communicate with the connection structure 50 in the other stack layer 30 through the first bonding structure 40, thus enabling electrical interconnection between the stack layers 30 after being stacked. The present application is not limited in the shape of the first mark 94.

In an example, in which the semiconductor structure 100 includes a first insulating layer 60, before connecting the stack layers 30, a part of the first insulating layer 60 needs to be formed on the stack layer 30, in order to form a part of the first bonding structure 40 to be connected with the stack layer 30. Here, a first mark 94 may be disposed at the side of the stack layer 30 facing the first insulating layer 60. It can be understood that if the first mark 94 is formed before formation of a part of the first insulating layer 60 on the stack layer 30, the first mark 94 is located on the surface of the stack layer 30 facing the first insulating layer 60; if the first mark 94 is formed after formation of a part of the first insulating layer 60 on the stack layer 30, the first mark 94 is located in the first insulating layer 60. In the above-described example, the first mark 94 may also be disposed in a stack layer 30 and likewise enable alignment between two stack layers 30.

Referring to FIG. 1, in the above-described example, the first bonding structure 40 may be formed by bonding two metal pads together. Two stack layers 30 are connected through the first bonding structure 40. The first bonding structure 40 includes a first connection section 41 and a second connection section 42 disposed in the stacking direction of the stack layers 30. The first connection section 41 and the second connection section 42 are both metal pads and have the same structure. Here, the first connection section 41 is connected with one of two adjacent stack layers 30, while the second connection section 42 is connected with the other of the two adjacent stack layers 30. Illustratively, the metal pad includes a metal material that is electrically conductive, for example, copper.

In combination with the above-described example, in which the semiconductor structure 100 includes the first insulating layer 60, the first insulating layer 60 may include a first insulating sublayer 61 and a second insulating sublayer 62. In two adjacent stack layers 30, the first insulating sublayer 61 covers a side of a first stack layer 30 facing a second stack layer 30 and the second insulating sublayer 62 covers a side of the second stack layer 30 facing the first stack layer 30. The first connection section 41 extends through the first insulating sublayer 61 to connect with the first stack layer 30, with a side of the first connection section 41 away from the first stack layer 30 being flush with a side of the first insulating sublayer 61 away from the first stack layer 30; the second connection section 42 extends through the second insulating sublayer 62 to connect with the second stack layer 30, with a side of the second connection section 42 away from the second stack layer 30 being flush with a side of the second insulating sublayer 62 away from the second stack layer 30. The first connection section 41 and the second connection section 42 form the first bonding structure 40. The first insulating sublayer 61 and the second insulating sublayer 62 form the first insulating layer 60 and have no gaps therebetween in the stacking direction of the stack layers 30. In the direction perpendicular to the stacking direction of the stack layers 30, the first insulating layer 60 covers the sidewalls of the first connection section 41 and the second connection section 42.

Referring to FIG. 4, in the above-described example, the first bonding structure 40 may also be formed by bonding two bumps together. Two stack layers 30 are connected through the first bonding structure 40. The first bonding structure 40 includes a first connection block 53, a fusion block 54 and a second connection block 55 disposed in the stacking direction of the stack layers 30. The first connection block 53 and a part of the fusion block 54 connected therewith form one bump, and the second connection block 55 and a part of the fusion block 54 connected therewith form another bump. The two bumps have the same structure. The first connection block 53 is connected with one of the two adjacent stack layers 30 and the second connection block 55 is connected with the other one of the two adjacent stack layers 30. Illustratively, the first connection block 53 and the second connection block 55 include metal material that is electrically conductive, such as copper, nickel. The fusion block 54 includes conductive metal material having a low melting point, such as tin, nickel-tin alloy, to facilitate connection between the first connection block 53 and the second connection block 55 through the fusion block 54, resulting in formation of the first bonding structure 40.

In combination with the above-described example, in which the semiconductor structure 100 includes the first insulating layer 60, the first insulating layer 60 may include a first insulating sublayer 61 and a second insulating sublayer 62. In two adjacent stack layers 30, the first insulating sublayer 61 covers the side of the first stack layer 30 facing the second stack layer 30 and the second insulating sublayer 62 covers the side of the second stack layer 30 facing the first stack layer 30. The first connection block 53 extends through the first insulating sublayer 61 to connect with the first stack layer 30. The side of the first connection block 53 away from the first stack layer 30 is connected with the fusion block 54. The fusion block 54 protrudes above the side of the first insulating sublayer 61 away from the first stack layer 30. The bump formed by the fusion block 54 and the first connection block 53 has a U-shape, e.g. is a U-Bump. The second connection section 42 extends through the second insulating sublayer 62 to connect with the second stack layer 30. The side of the second connection block 55 away from the second stack layer 30 is connected with the fusion block 54. The fusion block 54 protrudes above the side of the second insulating sublayer 62 away from the second stack layer 30. The bump formed by the fusion block 54 and the second connection block 55 has a U-shape, e.g. is a U-Bump. The first connection block 53, the fusion block 54 and the second connection block 55 form the first bonding structure 40. The first insulating sublayer 61 and the second insulation sublayer 62 form the first insulating layer 60 and have a first gap therebetween in the stacking direction of the stack layers 30. The first connection block 53 is at least partially located in the first insulating sublayer 61 and the second connection block 55 is at least partially located in the second insulating sublayer 62.

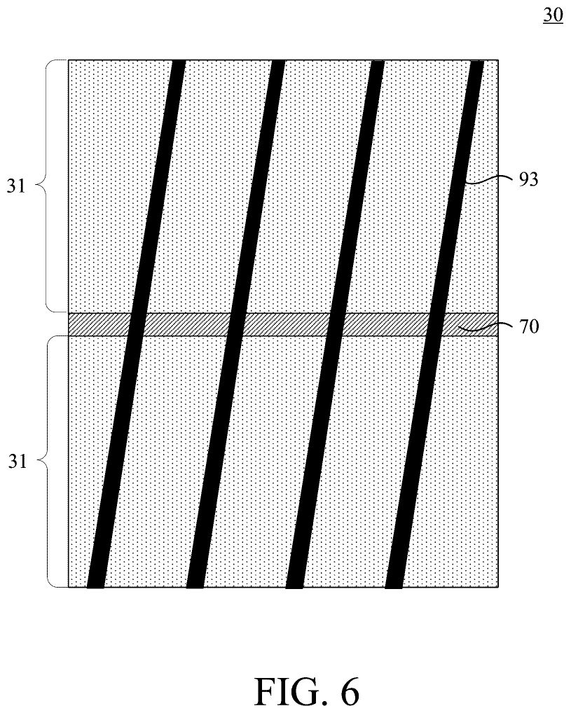

Referring to FIGS. 1 and 6, in the example of the present application, the semiconductor structure 100 further includes the second insulating layer 70 located between two adjacent device layers 31 with the second bonding structure 32 located in the second insulating layer 70. In combination with an implementation, in which the plurality of device layers 31 are connected through the second bonding structures 32 to form the stack layers 30, dicing traces 93 are present on side walls of the device layers 31 and side walls of the second insulating layers 70, so that the dicing traces 93 on the side walls of the two device layers 31 connected through the same second bonding structure 32 are continuous.

Referring to FIGS. 3 and 5, in an implementation, in which two device layers 31 are connected through the second bonding structure 32 to form a stack, a second mark 95 is disposed at a side of one device layer 31 to be connected with another device layer 30, the second mark 95 is configured for alignment between the device layers 31. Illustratively, during interconnection of the device layers 31, the second mark 95 on one device layer 31 should be aligned with the second mark 95 on the other device layer 31, so that the connection structure 50 in one device layer 31 may communicate with the connection structure 50 in the other device layer 31 through the second bonding structure 32, enabling electrical interconnection of the device layers 31 after being stacked. The present application is not limited in the shape of the second mark 95.

In an example, in which the semiconductor structure 100 includes a second insulating layer 70, before connecting the device layers 31, a part of the second insulating layer 70 needs to be formed on the device layer 31 in order to form a part of the second bonding structure 32 to be connected with the device layer 31. Here, the second mark 95 may be disposed at the side of a device layer 31 facing the second insulating layer 70. It can be understood that if the second mark 95 is formed before formation of the part of the second insulating layer 70 on the device layer 31, the second mark 95 is located on the surface of the device layer 31 facing the second insulating layer 70; if the second mark 95 is formed after formation of the part of the second insulating layer 70 on the device layer 31, the second mark 95 is located in the second insulating layer 70. In the above-described example, the second mark 95 may also be disposed in the device layer 31 and likewise enable alignment between two device layers 31.

In combination with an example, in which dicing streets are formed between respective device layers 31 on the same wafer, the second marks 95 may be disposed in the dicing streets, so that after dicing along the dicing streets, the second marks 95 are removed; the second marks 95 may be partially disposed in the dicing streets and after dicing along the dicing streets, the left part of the second marks 95 are located at the side of the device layer 31 facing the second insulating layer 70 and at the end proximate to the side wall of the device layer 31.

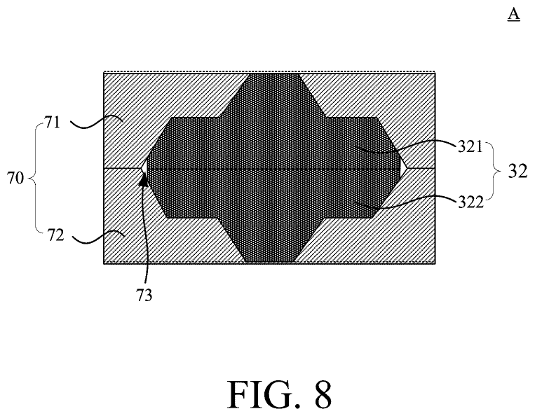

Referring to FIGS. 1 and 8, in the above-described example, the second bonding structure 32 may be formed by bonding two metal blocks together. Two device layers 31 are connected through the second bonding structure 32. The second bonding structure 32 includes a third connection section 321 and a fourth connection section 322 disposed in the stacking direction of the device layers 31. The third connection section 321 and the fourth connection section 322 are both metal blocks and have the same structure. Here, the third connection section 321 is connected with one of two adjacent device layers 31, while the fourth connection section 322 is connected with the other of the two adjacent device layers 31. Illustratively, the metal pad includes a metal material that is electrically conductive, for example, copper.

In combination with the above-described example, in which the semiconductor structure 100 includes the second insulating layer 70, the second insulating layer 70 may include a third insulating sublayer 71 and a fourth insulating sublayer 72. In two adjacent device layers 31, the third insulating sublayer 71 covers the side of the first device layer 31 facing the second device layer 31 and the fourth insulating sublayer 72 covers the side of the second device layer 31 facing the first device layer 31. The third connection section 321 extends through the third insulating sublayer 71 to connect with the first device layer 31, with the side of the third connection section 321 away from the first device layer 31 being flush with the side of the third insulating sublayer 71 away from the first device layer 31; the fourth connection section 322 extends through the fourth insulating sublayer 72 to connect with the second device layer 31, with the side of the fourth connection section 322 away from the second device layer 31 being flush with the side of the fourth insulating sublayer 72 away from the second device layer 31. The third connection section 321 and the fourth connection section 322 form the second bonding structure 32. The third insulating sublayer 71 and the fourth insulating sublayer 72 form the second insulating layer 70 and have no gaps therebetween in the stacking direction of the device layers 31.

In an implementation, in which the third connection section 321 and the fourth connection section 322 include copper, during connection of the third connection section 321 and the fourth connection section 322, their volume would increase first and then decrease, and second gaps 73 may be formed between the finally formed second bonding structure 32 and the second insulating layer 70 in the direction perpendicular to the stacking direction of the device layers 31.

Referring to FIG. 3, in some examples, the semiconductor structure 100 further includes a logic layer 80 and a plurality of stack layers 30 that are stacked are disposed on a side of the logic layer 80 and a plurality of device layers 31 in the stack layers 30 are all electrically connected with the logic layer 80. Logic circuits may be disposed in the logic layer 80 and configured for accessing the data in the device layers 31.

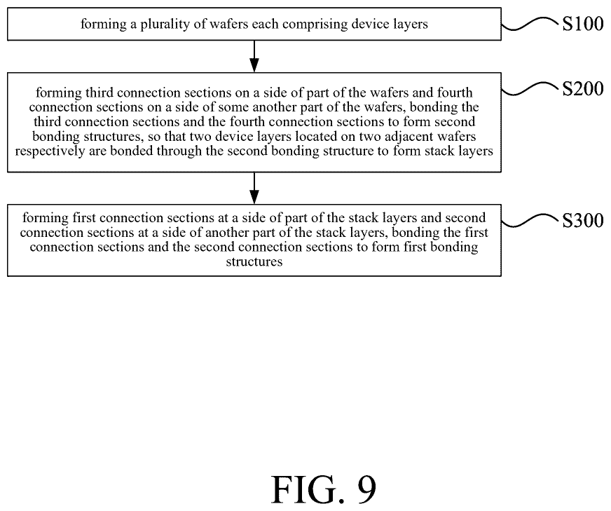

A fabrication method of a semiconductor structure is further provided in an example of the present application. Referring to FIG. 9, the fabrication method may include operations S100-S300.

In operation S100, a plurality of wafers including device layers are formed.

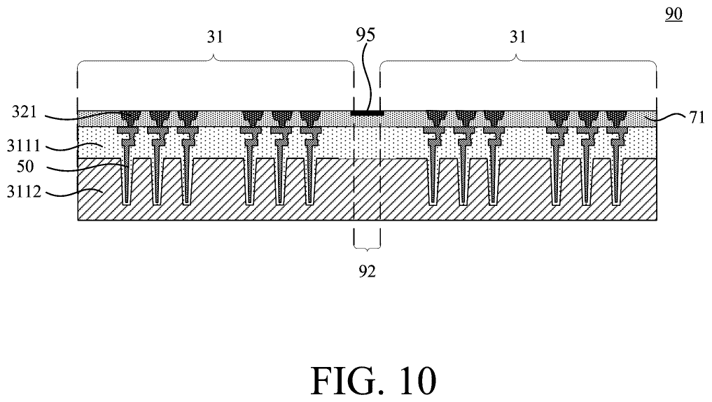

Referring to FIG. 10, in operation S100, a plurality of device layers 31 are formed on a wafer 90 and the device layer 31 includes a first device sublayer 3111 and a second device sublayer 3112. On the same wafer 90, a plurality of device sublayer 3111 are located in the same plane and a plurality of second device sublayer 3112 are located in the same plane. Here, the device layer 31 may include transistors disposed at the surface of the second device sublayer 3112 facing the first device sublayer 3111. The second device sublayer 3112 covers the first device sublayer 3111 and may serve as a substrate for protecting various devices in the device layer 31.

The plurality of device layers 31 are disposed in an array on the wafer 90 and spaced from each other. Each device layer 31 includes the first device sublayer 3111 and the second device sublayer 3112. The device layer 31 further includes a connection structure 50 extending through the first device sublayer 3111 and the second device sublayer 3112. The connection structure 50 has one end exposed at the side of the first device sublayer 3111 away from the second device sublayer 3112 and the other end exposed at the side of the second device sublayer 3112 away from the first device sublayer 3111. In such a configuration, the connection structure 50 may enable interconnection of the plurality of device layers 31 in the stacking direction.

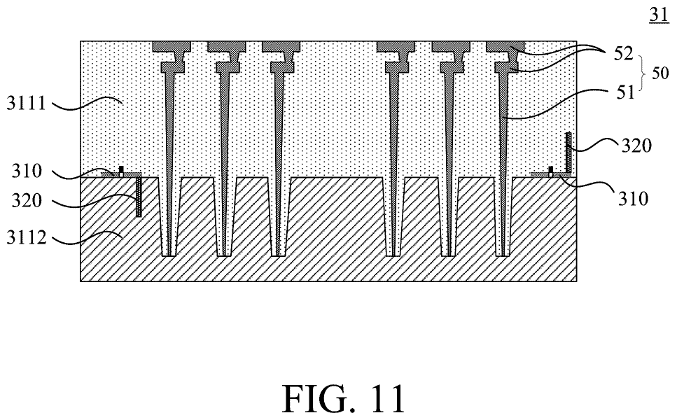

Referring to FIG. 11, in the above-described example, the connection structure 50 may include a vertical connection contact 51 and a connection wire 52. The vertical connection contact 51 is configured for connecting with various devices (e.g., transistors) in the device layer 31 and the connection wire 52 is configured for connecting with the second bonding structure 32 to enable interconnection of the plurality of device layers 31 in the stacking direction. Here, the vertical connection contacts 51 may be formed first and then various devices and connection wires 52 can be formed in the device layer 31; or the various devices and the connection wires 52 are formed in the device layer 31 first and then the vertical connection contacts 51 are formed; or the various devices are formed in the device layer 31 first, then the vertical connection contacts 51 are formed and then the connection wires 52 are formed.

In operation S200, third connection sections are formed on a side of part of the wafers and fourth connection sections are formed on a side of another part of the wafers, with the third connection sections and the fourth connection sections bonded to form the second bonding structures, so that two device layers located on two adjacent wafers respectively may be bonded through the second bonding structure to form the stack layer.

Referring to FIGS. 10, 12 and 13, in operation S200, forming the second bonding structures 32 may include: forming second insulating section on a side of the wafer 90; forming third connection sections 321 on part of the second insulating section; and forming fourth connection sections 322 on another part of the second insulating section, wherein the second insulating section may include a third insulating sublayer 71 or a fourth insulating sublayer 72.

Illustratively, based on the plurality of wafers 90 formed as described above, the third insulating sublayers 71 are formed on a side of part of the wafers 90 to cover the plurality of device layers 31 on the wafers 90; then the third connection sections 321 extending through the third insulating sublayers 71 are formed on the third insulating sublayers 71 and connected with the connection structures 50 in the device layers 31 covered by the third insulating sublayers 71.

Fourth insulating sublayers 72 are formed on a side of another part of the wafers 90 to cover the plurality of device layers 31 on the wafers 90; then the fourth connection sections 322 extending through the fourth insulating sublayers 72 are formed on the fourth insulating sublayers 72 and connected with connection structures 50 in the device layers 31 covered by the fourth insulating sublayers 72.

Then the third connection sections 321 are adhered to the fourth connection sections 322, while the third insulating sublayers 71 are adhered to the fourth insulating sublayers 72. Through heat treatment, the third connection sections 321 and the fourth connection sections 322 are bonded together to form the second bonding structures 32, at the same time, the third insulating sublayers 71 and the fourth insulating sublayers 72 form the second insulating layers 70. As such, two wafers 90 are bonded together.

In some implementations, all of the second insulating sections may be formed on the same side of the wafers 90. Illustratively, in an implementation, in which the device layer 31 includes the first device sublayer 3111 and the second device sublayer 3112, the third insulating sublayers 71 may cover the first device sublayers 3111 in some wafers 90 and the fourth insulating sublayers 72 may cover the first device sublayers 3111 in some other wafers 90. After connecting the third connection sections 321 and the fourth connection sections 322 together, the first device layers 3111 on two wafers 90 are proximate to each other.

Alternatively, the third insulating sublayers 71 cover the second device sublayers 3112 in some wafers 90, while the fourth insulating sublayers 72 cover the second device sublayers 3112 in some other wafers 90. After connecting the third connection sections 321 and the fourth connection sections 322 together, the second device layers 3112 on two wafers 90 are proximate to each other.

In some other implementations, the second insulating sections may be formed on a side of part of the wafers 90 or on the other side of the part of the wafers 90. Illustratively, in an implementation, in which the device layer 31 includes the first device sublayer 3111 and the second device sublayer 3112, the third insulating sublayers 71 cover the first device sublayers 3111 in some wafers 90 and the fourth insulating sublayers 72 cover the second device sublayers 3112 in some other wafers 90. After connecting the third connection sections 321 and the fourth connection sections 322 together, the first device sublayers 3111 on one wafer 90 are proximate to the second device sublayers 3112 on the other wafer 90.

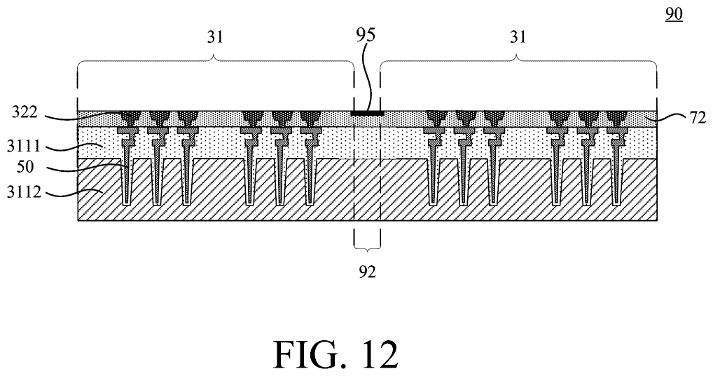

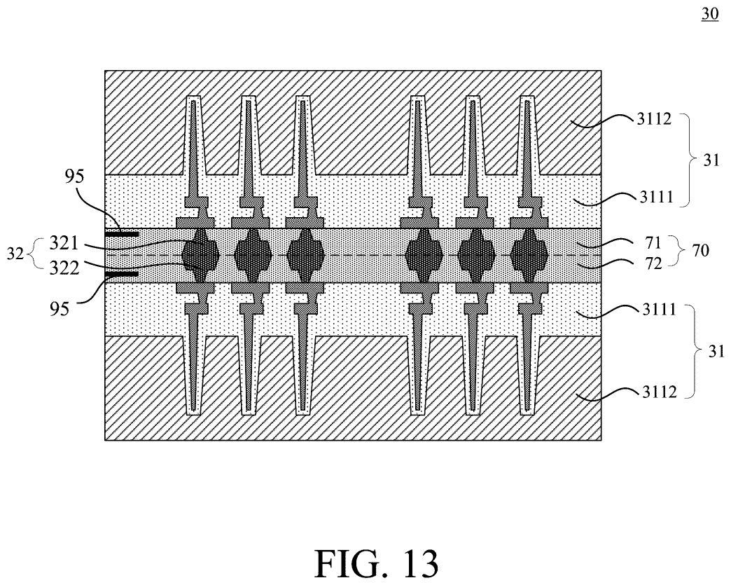

In some examples, referring to FIGS. 12 and 13, after bonding two adjacent wafer sets, the dicing streets 92 located on two wafers respectively correspond to each other; at least two wafers 90 after being bonded are diced along the dicing streets to form the stack layers 30. Here, the stack layer 30 includes a plurality of device layers 31 that are stacked.

In the above-described example, before bonding two wafers 90, the fabrication method of the semiconductor structure of the present application further includes forming second marks 95 that may be formed at the side of the device layers 31 facing the second bonding structure 32 and may be located entirely or partially in the dicing streets. The second marks 95 may be disposed in the dicing streets, so that after dicing along the dicing streets, the second marks 95 may be removed; the second marks 95 may also be partially disposed in the dicing streets and after dicing along the dicing streets, the left part of the second marks 95 are located at the side of the device layers 31 facing the second bonding structure 32 and at the end proximate to the side walls of the device layers 31.

If the second marks 95 are formed before formation of part of the second insulating layer 70 on the wafer 90, the second marks 95 are located on the surface of the device layer 31 facing the second insulating layer 70; if the second marks 95 are formed after formation of the part of the second insulating layer 70 on the wafer 90, the second marks 95 are located in the second insulating layer 70.

In operation S300, first connection sections are formed at a side of part of the stack layers and second connection sections are formed at a side of another part of the stack layers; the first connection sections and the second connection sections are bonded to form first bonding structures.

In operation S300, forming the first bonding structures 40 includes forming the first insulating section at a side of the stack layers 30.

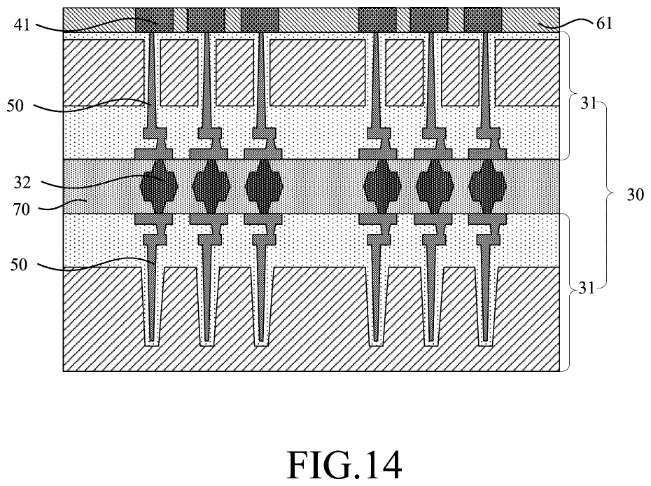

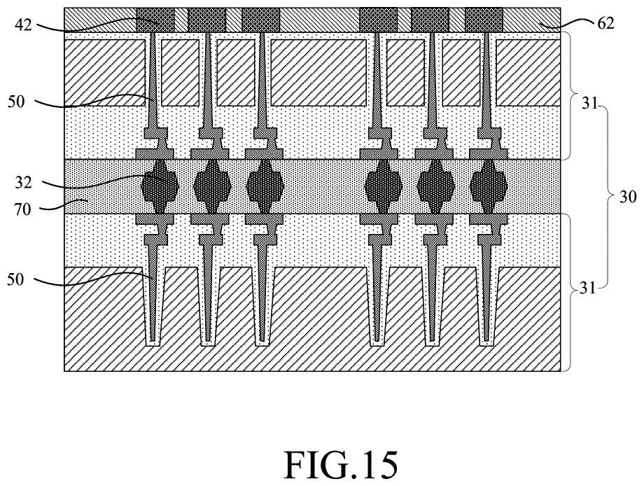

Referring to FIGS. 14 and 15, in some examples, the first connection sections 41 are formed on part of the first insulating section, while the second connection sections 42 are formed on another part of the first insulating section; wherein the first insulating section may include a first insulating sublayer 61 or a second insulating sublayer 62.

Illustratively, based on the plurality of stack layers 30 formed as described above, the first insulating sublayers 61 are formed on a side of part of the stack layers 30 to cover the stack layers 30; then the first connection sections 41 extending through the first insulating sublayers 61 are formed on the first insulating sublayers 61 and connected with the connection structures 50 in the device layers 31 of the stack layers 30 covered by the first insulating sublayers 61. The side of the formed first connection sections 41 away from the stack layers 30 is flush with the side of the first insulating sublayers 61 away from the stack layers 30.

The second insulating sublayers 62 are formed on a side of another part of the stack layers 30 to cover the stack layers 30; then second connection sections 42 extending through the second insulating sublayers 62 are formed on the second insulating sublayers 62 and connected with the connection structures 50 in the device layers 31 of the stack layers 30 covered by the second insulating sublayers 62. The side of the second connection sections 42 away from the stack layers 30 is flush with the side of the second insulating sublayers 62 away from the stack layers 30.

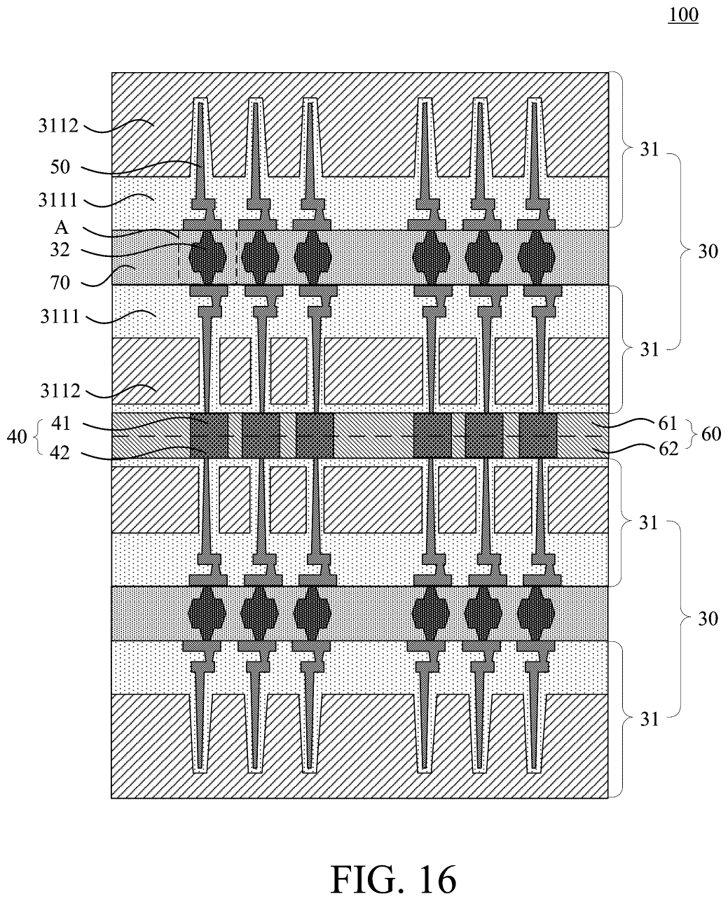

Referring to FIG. 16, the first connection sections 41 are adhered to the second connection sections 42, while the first insulating sublayers 61 are adhered to the second insulating sublayers 62; through heat treatment, the first connection sections 41 and the second connection sections 42 are bonded together to form the first bonding structures 40, at the same time, the first insulating sublayers 61 and the second insulating sublayers 62 form the first insulating layers 60 and have no gap therebetween in the stacking direction of the stack layers 30; in the direction perpendicular to the stacking direction of the stack layers 30, the first insulating layers 60 cover the side walls of the first connection sections 41 and the second connection sections 42. As such, two stack layers 30 are bonded together to form the semiconductor structure 100.

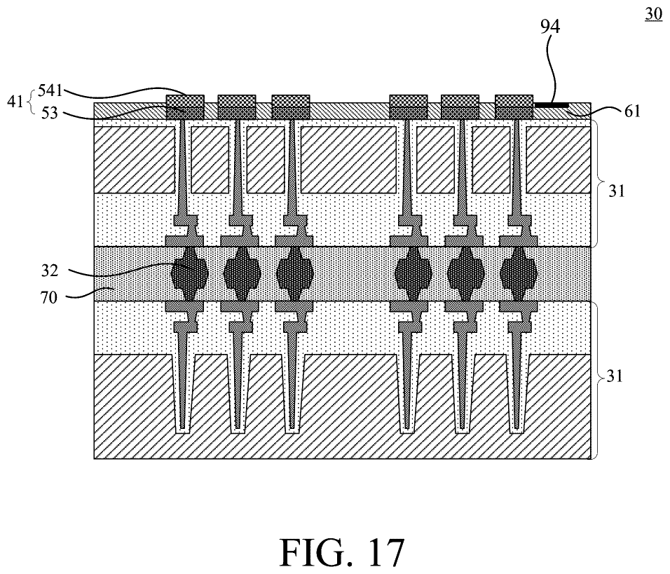

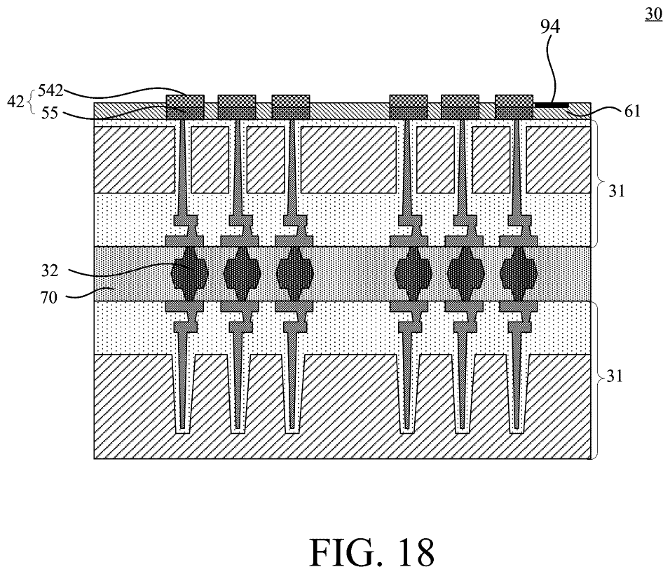

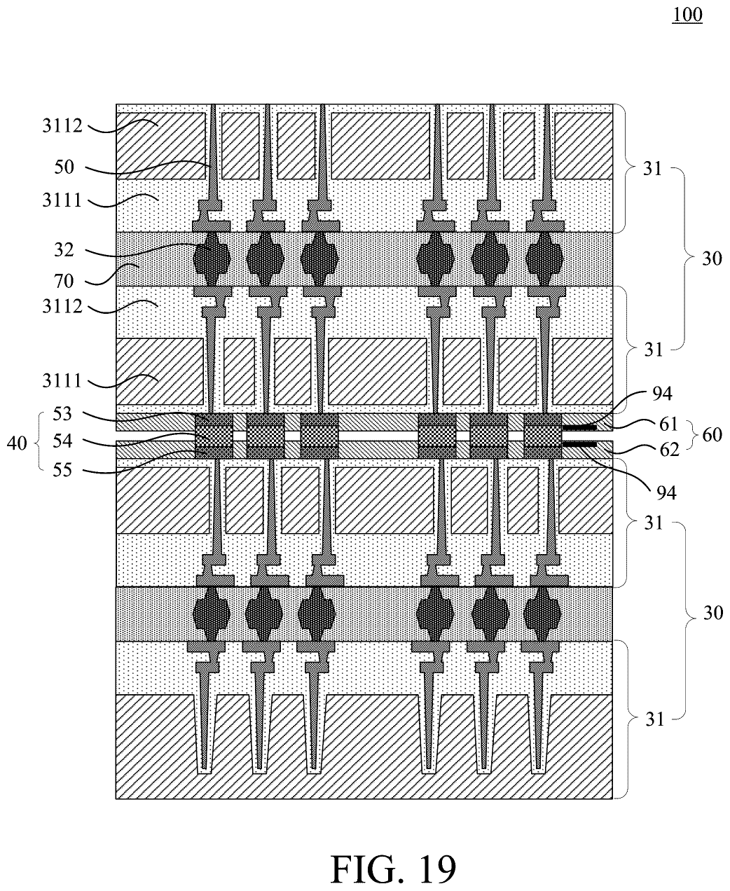

Referring to FIGS. 17, 18 and 19, in the above-described example, the formed first connection section 41 may include a first connection block 53 and a first initial fusion block 541 formed on the first insulating sublayer 61; the first connection block 53 is connected with the connection structure 50 in the device layer 31 of the stack layer 30 covered by the first insulating sublayer 61; the first initial fusion block 541 is formed on a side of the first connection block 53 away from the stack layer 30 and protrudes above a side of the first insulating sublayer 61 away from the stack layer 30.

The formed second connection section 42 may include a second connection block 55 and a second initial fusion block 542 formed in the second insulating sublayer 62; the second connection block 55 is connected with the connection structure 50 in the device layer 31 of the stack layer 30 covered by the second insulating sublayer 62; the second initial fusion block 542 is formed on a side of the second connection block 55 away from the stack layer 30 and protrudes above a side of the second insulating sublayer 62 away from the stack layer 30.

Finally, the first initial fusion block 541 and the second initial fusion block 542 are adhered to each other and connected through heat treatment to form the first bonding structure 40, while a first gap is formed between the first insulating sublayer 61 and the second insulating sublayer 62 in the stacking direction of the stack layers 30.

In the above-described example, before bonding two stack layers 30, the fabrication method of the semiconductor structure in the present application further includes forming the first marks 94 that may be formed at a side of the stack layer 30 facing the first bonding structure 40.

If the first marks 94 are formed before forming part of the first insulating layer 60 on the stack layer 30, the first marks 94 are located on the surface of the stack layer 30 facing the first insulating layer 60; if the first marks 94 are formed after formation of the part of the first insulating layer 60 on the stack layer 30, the first marks 94 are located in the first insulating layer 60.

In the above-described examples, the stacked wafer sets are diced first to form the stack layers 30 and then the stack layers 30 are connected through the first bonding structures 40 to form the semiconductor structure 100. During this process, the stack layers 30 with poor performance may be removed, and the subsequent operations of forming the semiconductor structure 100 may only proceed with the stack layers 30 with qualified performance, thus improving the yield of semiconductor structure 100.

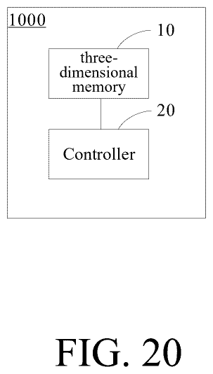

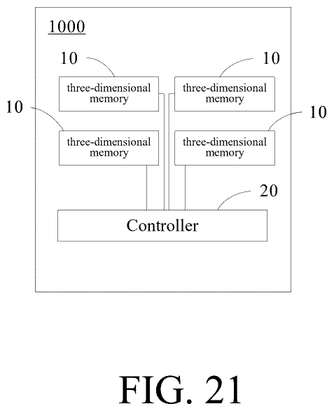

Referring to FIGS. 20 and 21, some examples of the present application further provide a memory system 1000. The memory system 1000 includes a controller 20 and a three-dimensional memory 10. The three-dimensional memory 10 may include the above-described semiconductor structure 100. The controller 20 is coupled to the three-dimensional memory 10 to control the three-dimensional memory 10 to store data.

The memory system 1000 can be integrated into various types of storage devices, for example, be included in the same package, such as a universal flash storage (UFS) package or an embedded multi media card (eMMC) package. That is, the memory system 1000 may be applied to and packaged into different kinds of electronic products such as a mobile phone (e.g., a cellphone), a desktop computer, a tablet computer, a laptop computer, a server, a vehicle-mounted device, a gaming console, a printer, a positioning device, a wearable device, a smart sensor, a mobile power source, a virtual reality (VR) device, an augmented reality (AR) device, or any other suitable electronic device having storage therein.

In some examples, with reference to FIG. 20, the memory system 1000 includes a controller 20 and a three-dimensional memory 10 and may be integrated into a memory card.

The memory card may include any one of a PC card (the personal computer memory card international association, PCMCIA), a compact flash (CF) card, a smart media (SM) card, a memory stick, a multimedia card (MMC), a secure digital (SD) memory card and a UFS.

In some other examples, with reference to FIG. 21, the memory system 1000 includes a controller 20 and a plurality of three-dimensional memories 10 and is integrated into a solid state drive (SSD).

In the memory system 1000, in some examples, the controller 20 is configured to operate in a low duty-cycle environment like an SD card, a CF card, a universal serial bus (USB) flash drive or other medium for use in an electronic device, such as a personal computer, a digital camera, a mobile phone, etc.

In some other examples, the controller 20 is configured to operate in a high duty-cycle environment like an SSD or an eMMC, used as a data storage for a mobile device such as a smart phone, a tablet computer or a laptop computer, and an enterprise storage array.

In some examples, the controller 20 may be configured to manage the data stored in each three-dimensional memory 10 and communicates with an external device (e.g., a host). In some examples, the controller 20 can be configured to control operations of the three-dimensional memory 10, such as read, erase, and program operations. In some examples, the controller 20 may also be configured to manage various functions with respect to the data stored or to be stored in the memory 10, including at least one of bad-block management, garbage collection, logical-to-physical address conversion, wear leveling, etc. In some examples, the controller 20 is further configured to process error correction codes with respect to the data read from or written to the three-dimensional memory 10.

Of course, the controller 20 may also perform any other suitable functions, for example, formatting the three-dimensional memory 10; for example, the controller 20 can communicate with an external device (e.g., a host) according to at least one of various interface protocols.

It is to be noted that the interface protocol includes at least one of a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol and a Firewire protocol.

Some examples of the present application further provide an electronic device. The electronic device may be any one of a cellphone, a desktop computer, a tablet computer, a laptop computer, a server, a vehicle-mounted device, a wearable device (e.g., a smart watch, a smart bracelet, and smart glasses), a mobile power source, a gaming console and a digital multimedia player.

The electronic device may include the above-described memory system 1000 and may further include any one of a central processing unit (CPU) and a cache.

Examples of the present application provide a semiconductor structure and a fabrication method thereof, which are intended to increase the number of the device layers packaged into the semiconductor structure and in turn to improve the total capacity of the memory.

For the purpose above, examples of the present application employ the following technical solutions.

In one aspect, an example of present application provides a semiconductor structure. The semiconductor structure includes: a plurality of stack layers that are stacked; and a first bonding structure located between two adjacent stack layers of the plurality of stack layers, with the two adjacent stack layers connected together through the first bonding structure, wherein the stack layer includes a plurality of device layers that are stacked and a second bonding structure located between two adjacent device layers of the plurality of device layers, with the two adjacent device layers connected through the second bonding structure.

In some examples, the semiconductor structure further includes a first insulating layer and a second insulating layer, the first insulating layer is located between two adjacent stack layers of the plurality of stack layers, the first bonding structure is located in the first insulating layer and the second bonding structure is located in the second insulating layer; the semiconductor structure further includes a first mark and a second mark, with the first mark located in the stack layer, or in the first insulating layer, or between the stack layer and the first insulating layer, and the second mark located in the device layer, or in the second insulating layer, or between the device layer and the second insulating layer.

In some examples, the first bonding structure includes a first connection section and a second connection section disposed in a stacking direction of the stack layers, with the first connection section connected with one of the two adjacent stack layers and the second connection section connected with the other of the two adjacent stack layers; and the second bonding structure includes a third connection section and a fourth connection section disposed in a stacking direction of the device layers, with the third connection section connected with one of the two adjacent device layers and the fourth connection section connected with the other of the two adjacent device layers.

In some examples, in a direction perpendicular to the stacking direction of the stack layers, the first insulating layer covers side walls of the first connection section and the second connection section.

In some examples, the first bonding structure includes a first connection block, a fusion block and a second connection block disposed in the stacking direction of the stack layers, with the first connection block connected with one of the two adjacent stack layers and the second connection block connected with the other of the two adjacent stack layers; and the second bonding structure includes a third connection section and a fourth connection section disposed in the stacking direction of the device layers, with the third connection section connected with one of the two adjacent device layers and the fourth connection section connected with the other of the two adjacent device layers.

In some examples, the first insulating layer includes a first insulating sublayer and a second insulating sublayer that have a first gap therebetween in the stacking direction of the stack layers; and the first connection block is at least partially located in the first insulating sublayer and the second connection block is at least partially located in the second insulating sublayer and connected with the stack layer adjacent to the second insulating sublayer.

In some examples, both the first connection block and the second connection block include at least one of copper and nickel and the fusion block includes nickel-tin alloy.

In some examples, in a direction perpendicular to the stacking direction of the device layers, a second gap is disposed between the second bonding structure and the second insulating layer.

In some examples, the device layer includes a first device sublayer, a second device sublayer and a connection structure, the first device sublayer has transistors disposed therein, the second device sublayer is on a side of the first device sublayer and covers the first device sublayer to protect the second device sublayer, and the connection structure extends through the first device sublayer and the second device sublayer and is configured for connecting with the transistors in the first device sublayer; and an end of the connection structure away from the second device sublayer is connected with the second bonding structure.

In some examples, the device layer includes a first device sublayer, a second device sublayer and a connection structure, the first device sublayer has transistors disposed therein, the second device sublayer covers the first device sublayer to protect the second device sublayer, and the connection structure extends through the first device sublayer and the second device sublayer and is configured for connecting with the transistors in the second device sublayer; and an end of the connection structure away from the first device sublayer is connected with the second bonding structure.

In some examples, the device layer includes a first device sublayer, a second device sublayer and a connection structure, the first device sublayer has transistors disposed therein, the second device sublayer covers the first device sublayer to protect the second device sublayer, and the connection structure extends through the first device sublayer and the second device sublayer and is configured for connecting with the transistors in the second device sublayer; and among the two adjacent device layers, an end of the connection structure in one device layer away from its second device sublayer is connected with an end of the connection structure in the other device layer away from its first device sublayer through the second bonding structure.

In some examples, dicing traces are continuous on the side walls of two device layers connected through the same second bonding structure.

In some examples, dicing traces are discontinuous on the side walls of two device layers connected through the same first bonding structure.

In some examples, the second mark is located at a side of the device layer facing the second bonding structure and at an end proximate to the side wall of the device layer.

In some examples, the semiconductor structure further includes a logic layer, wherein the plurality of stack layers are disposed on a side of the logic layer and a plurality of device layers are all connected with the logic layer.

In some examples, a semiconductor structure provided by an example of the present application includes: a plurality of stack layers that are stacked, a first insulation layer, a first mark and a first bonding structure, wherein the stack layer includes a plurality of device layers that are stacked, the first insulation layer is located between two adjacent stack layers, the first mark is located in the stack layer, or in the first insulating layer, or between the stack layer and the first insulating layer, and the first bonding structure is located in the first insulating layer and includes a first connection block, a fusion block and a second connection block disposed in a stacking direction of the stack layers, with the first connection block connected with one of the two adjacent stack layers and the second connection block connected with the other of the two adjacent stack layers; wherein the stack layer includes a second insulation layer and a second bonding structure, with the second insulating layer located between two adjacent device layers, and the second bonding structure located in the second insulating layer, the second bonding structure includes a third connection section and a fourth connection section disposed in a stacking direction of the device layers, with the third connection section connected with one of the two adjacent device layers and the fourth connection section connected with the other of the two adjacent device layers.

In another aspect, examples of the present application further provide a fabrication method of a semiconductor structure, which includes: forming a plurality of wafers each including device layers; forming third connection sections on a side of part of the plurality of wafers and fourth connection sections on a side of another part of the plurality of wafers, wherein the third connection sections and the fourth connection sections are bonded to form second bonding structures, so that two device layers located on two adjacent wafers respectively are bonded through the second bonding structure to form the stack layer; and forming first connection sections at a side of part of the stack layers and second connection sections at a side of another part of the stack layers, wherein the first connection sections and the second connection sections are bonded to form first bonding structures.

In some examples, the wafer includes a plurality of device layers spaced from each other, and after the two adjacent wafers are bonded, spacings between the device layers on the two adjacent wafers respectively communicate with each other correspondingly to form dicing streets; and at least two wafers that are bonded are diced along the dicing streets to form stack layers.

In some examples, forming the second bonding structure further includes: forming second insulating section on a side of the device layers; forming third connection sections on part of the second insulating section and fourth connection sections on another part of the second insulating section; adhering the third connection sections to the fourth connection sections and bonding the third connection sections and the fourth connection sections together through heat treatment to form the second bonding structure.

In some examples, forming the first bonding structure further includes: forming first insulating section on a side of the stack layer; forming first connection sections on part of the first insulating section and second connection sections on another part of the first insulating section; and adhering the first connection sections to the second connection sections and bonding the first connection sections and the second connection sections together through heat treatment to form the first bonding structure.

In some examples, forming the first bonding structure further includes: forming first insulating section on a side of the stack layer; forming first connection blocks and first initial fusion blocks on part of the first insulating section and forming second connection blocks and second initial fusion blocks on another part of the first insulating section; and adhering the first initial fusion blocks to the second initial fusion blocks and bonding the first initial fusion blocks and the second initial fusion blocks together through heat treatment to form first bonding structures.

In yet another aspect, examples of the present application further provide a memory system including the above-described semiconductor structure and a controller coupled to the semiconductor structure to control the semiconductor structure to store data.

In yet another aspect, examples of the present application further provide an electronic apparatus including a memory system and a host coupled to the memory system.

What have been described above are only specific implementations of the present application. However, the scope of the present application is not limited thereto, and variations or substitutions that easily occur to those skilled in the art within the technical scope disclosed by the present application should be encompassed in the scope claimed by the present application. Therefore, the scope of the present application should be determined by the scope of the claims.

What is claimed is:

1. A semiconductor structure, comprising:
a plurality of stack layers that are stacked; and
a first bonding structure located between two adjacent stack layers of the plurality of stack layers, with the two adjacent stack layers connected through the first bonding structure,
wherein the stack layer includes a plurality of device layers that are stacked and a second bonding structure located between two adjacent device layers of the plurality of device layers, with the two adjacent device layers connected through the second bonding structure.

2. The semiconductor structure of claim 1, wherein the semiconductor structure further includes a first insulating layer and a second insulating layer, the first insulating layer is located between the two adjacent stack layers, the first bonding structure is located in the first insulating layer and the second bonding structure is located in the second insulating layer; the semiconductor structure further includes a first mark and a second mark, the first mark is located in the stack layer, or in the first insulating layer, or between the stack layer and the first insulating layer, and the second mark is located in the device layer, or in the second insulating layer, or between the device layer and the second insulating layer.

3. The semiconductor structure of claim 1, wherein the first bonding structure includes a first connection section and a second connection section disposed in a stacking direction of the stack layers, the first connection section is connected with one of the two adjacent stack layers and the second connection section is connected with the other of the two adjacent stack layers; and
the second bonding structure includes a third connection section and a fourth connection section disposed in a stacking direction of the device layers, the third connection section is connected with one of the two adjacent device layers and the fourth connection section is connected with the other of the two adjacent device layers.

4. The semiconductor structure of claim 3, wherein in a direction perpendicular to the stacking direction of the stack layers, a first insulating layer covers side walls of the first connection section and the second connection section.

5. The semiconductor structure of claim 1, wherein the first bonding structure includes a first connection block, a fusion block and a second connection block disposed in a stacking direction of the stack layers, with the first connection block connected with one of the two adjacent stack layers and the second connection block connected with the other of the two adjacent stack layers; and
the second bonding structure includes a third connection section and a fourth connection section disposed in a stacking direction of the device layers, with the third connection section connected with one of the two adjacent device layers and the fourth connection section connected with the other of the two adjacent device layers.

6. The semiconductor structure of claim 5, wherein a first insulating layer includes a first insulating sublayer and a second insulating sublayer that have a first gap therebetween in the stacking direction of the stack layers; and
the first connection block is at least partially located in the first insulating sublayer and connected with the stack layer adjacent to the first insulating sublayer, and the second connection block is at least partially located in the second insulating sublayer and connected with the stack layer adjacent to the second insulating sublayer.

7. The semiconductor structure of claim 5, wherein both the first connection block and the second connection block includes at least one of copper and nickel, and the fusion block includes nickel-tin alloy.

8. The semiconductor structure of claim 2, wherein in a direction perpendicular to the stacking direction of the device layers, a second gap is disposed between the second bonding structure and the second insulating layer.

9. The semiconductor structure of claim 1, wherein the device layer includes a first device sublayer, a second device sublayer and a connection structure, the first device sublayer has transistors disposed therein, the second device sublayer is located on a side of the first device sublayer and covers the first device sublayer to protect the second device sublayer; and the connection structure extends through the first device sublayer and the second device sublayer and is configured for connecting with the transistors in the first device sublayer; and
an end of the connection structure away from the second device sublayer is connected with the second bonding structure.

10. The semiconductor structure of claim 1, wherein the device layer includes a first device sublayer, a second device sublayer and a connection structure, the first device sublayer has transistors disposed therein, the second device sublayer is located on a side of the first device sublayer and covers the first device sublayer to protect the second device sublayer; and the connection structure extends through the first device sublayer and the second device sublayer and is configured for connecting with the transistors in the first device sublayer; and
an end of the connection structure away from the first device sublayer is connected with the second bonding structure.

11. The semiconductor structure of claim 1, wherein the device layer includes a first device sublayer, a second device sublayer and a connection structure, the first device sublayer has transistors disposed therein, the second device sublayer is located on a side of the first device sublayer and covers the first device sublayer to protect the second device sublayer; and the connection structure extends through the first device sublayer and the second device sublayer and is configured for connecting with the transistors in the first device sublayer; and
in the two adjacent device layers, an end of the connection structure away from the second device sublayer in one device layer is connected with an end of the connection structure away from the first device sublayer in the other device layer through the second bonding structure.

12. The semiconductor structure of claim 1, wherein dicing traces on side walls of two device layers of the plurality of device layers connected through the same second bonding structure are continuous and dicing traces on the side walls of two device layers of the plurality of device layers connected through the same first bonding structure are discontinuous.

13. The semiconductor structure of claim 1, wherein a second mark is located at a side of the device layer facing the second bonding structure and at an end proximate to a side wall of the device layer.

14. The semiconductor structure of claim 1, further includes a logic layer, wherein the plurality of stack layers are disposed on a side of the logic layer and the plurality of device layers are all connected with the logic layer.

15. A semiconductor structure, comprising:
a plurality of stack layers that are stacked, each of which includes a plurality of device layers that are stacked;
a first insulation layer located between two adjacent stack layers of the plurality of stack layers;
a first mark located in the stack layer, or in the first insulating layer, or between the stack layer and the first insulating layer; and
a first bonding structure located in the first insulating layer and including a first connection block, a fusion block and a second connection block disposed in a stacking direction of the stack layers, with the first connection block connected with one of two adjacent stack layers and the second connection block connected with the other of the two adjacent stack layers;
wherein the stack layers includes a second insulating layer and a second bonding structure, with the second insulating layer located between two adjacent device layers of the plurality of device layers, and the second bonding structure located in the second insulating layer; the second bonding structure includes a third connection section and a fourth connection section disposed in a stacking direction of the device layers, with the third connection section connected with one of the two adjacent device layers and the fourth connection section connected with the other of the two adjacent device layers.

16. A fabrication method of a semiconductor structure, comprising:
forming a plurality of wafers each including device layers;
forming third connection sections on a side of part of the wafers and fourth connection sections on a side of another part of the wafers, bonding the third connection sections and the fourth connection sections to form second bonding structures, so that two device layers located on two adjacent wafers respectively are bonded through the second bonding structure to form stack layers; and
forming first connection sections at a side of part of the stack layers and second connection sections at a side of another part of the stack layers, bonding the first connection sections and the second connection sections to form first bonding structures.

17. The fabrication method of claim 16, wherein the wafer includes a plurality of device layers spaced from each other, wherein after the two adjacent wafers are bonded, the spacings between the device layers on the two adjacent wafers respectively communicate with each other correspondingly to form dicing streets; and
dicing at least two of the wafers that are bonded along the dicing streets to form the stack layers.

18. The fabrication method of claim 17, wherein forming the second bonding structures further includes:
forming second insulating sections on a side of the device layers;
forming third connection sections on part of the second insulating sections and fourth connection sections on another part of the second insulating sections; and
adhering the third connection sections to the fourth connection sections and bonding the third connection sections and the fourth connection sections together through heat treatment to form the second bonding structures.

19. The fabrication method of claim 17, wherein forming the first bonding structures further includes:
forming first insulating sections on a side of the stack layers;
forming first connection sections on part of the first insulating sections and second connection sections on another part of the first insulating sections; and
adhering the first connection sections to the second connection sections and bonding the first connection sections and the second connection sections together through heat treatment to form the first bonding structures.

20. The fabrication method of claim 17, wherein forming the first bonding structures further includes:
forming first insulating sections on a side of the stack layers;
forming first connection blocks and first initial fusion blocks on part of the first insulating sections and forming second connection blocks and second initial fusion blocks on another part of the first insulating sections; and
adhering the first initial fusion blocks to the second initial fusion blocks and bonding the first initial fusion blocks and the second initial fusion blocks together through heat treatment to form the first bonding structures.
